(19) United States
(12) Patent Application Publication
(10) Pub. No.: US 2008/0185610 A1
(43) Pub. Date: Aug. 7, 2008

(54) RESIN-SEALED SEMICONDUCTOR LIGHT RECEIVING ELEMENT, MANUFACTURING METHOD THEREOF AND ELECTRONIC DEVICE USING THE SAME

(76) Inventors: Yuichiro KUSHIMATSU, Nara (JP); Hirofumi Shindoh, Mie (JP)

Correspondence Address: BIRCH STEWART KOLASCH & BIRCH, PO BOX 747, FALLS CHURCH, VA, 22040-0747, US

(21) Appl. No.: 12/023,566

(22) Filed: Jan. 31, 2008

(30) Foreign Application Priority Data
Feb. 2, 2007 (JP) 2007-024693

(51) Int. Cl. H01L 33/00; H01L 21/00

(52) U.S. Cl. 257/100; 438/33; 257/E33.001; 257/E21.001

(57) ABSTRACT

A resin-sealed semiconductor light receiving element in which a light receiving element mounted on a circuit board is sealed with a transparent resin. A mounting face of the circuit board on which the light receiving element is mounted is sealed with a transparent epoxy resin so that a light receiving surface of the light receiving element is exposed, and at least the light receiving surface of the light receiving element is sealed with a transparent silicone resin.

This application claims priority under 35 U.S.C. §119(a) on Patent Application No. 2007-024693 filed in Japan on Feb. 2, 2007, the entire content of which is herein incorporated by reference.

### BACKGROUND OF THE INVENTION

The present invention relates to a resin-sealed semiconductor light receiving element in which a light receiving element is sealed with a transparent resin, a manufacturing method thereof, and an electronic device using the same.

In the field of optical sensors, sensors for optical pickups and the like, resin-sealed devices are often used in which a semiconductor element chip is mounted on a substrate and sealed with a transparent resin (see JP 1-209733A, Japanese Patent No. 3702998, Japanese Patent No. 3710942, and JP 2004-79683A).

Typically, thermoset resin such as transparent epoxy resin or transparent silicone resin is used as the transparent sealing resin.

Sealing methods often used include resin sealing the semiconductor element chip by transfer molding using a die, or by dripping (potting) liquid resin into a mold around the placement area of the semiconductor element chip and thermosetting the liquid resin using an oven or the like.

In the field of optical pickups, on the other hand, the wavelength of semiconductor lasers is being reduced to enable high-density recording and reproduction, and in recent years optical pickups that use blue semiconductor lasers have been developed. And with light-receiving elements for use in the power monitors of semiconductor lasers, resin-sealed light receiving elements compatible with blue laser light have been commercialized.

Although transparent epoxy resin and transparent silicone resin are also typically used as the sealing resin for these light receiving elements, transparent epoxy resin is degraded by shortwave light such as blue light, adversely affecting transmittance. Therefore, transparent silicone resin having excellent light resistance to shortwave light is often used to seal light receiving elements for use in the power monitors of blue laser light.

FIG. 7 is a cross-sectional diagram showing a conventional resin-sealed semiconductor light receiving element in which the light receiving element is sealed by transparent silicone resin. In this conventional resin-sealed semiconductor light receiving element 101, a light receiving element chip 103 is mounted on a circuit board 102, electrodes of the light receiving element chip 103 are connected to wiring patterns of the circuit board 102 by bonding wires 104, and the mounting face of the circuit board 102, the light receiving element chip 103 and the bonding wires 104 are sealed by a transparent silicone resin 105.

However, with the conventional resin-sealed semiconductor light receiving element 101 such as shown in FIG. 7, the following problems arise because of using the transparent silicone resin 105 having excellent light resistance to short-wave light.

That is, the cure shrinkage rate of the transparent silicone resin 105 is high in comparison to transparent epoxy resin, creating greater internal stress on the cured resin (internal deformation). Therefore, with reliability tests such as the temperature cycle test, defects such as the bonding wires breaking inside the resin or the resin peeling from the interface with the circuit board readily occur, making the resin-sealed semiconductor light receiving element less reliable due to being less durable with respect to environmental changes such as temperature cycles in comparison to when transparent epoxy resin is used.

### SUMMARY OF THE INVENTION

In view of this, the present invention, which was proposed to solve the above problems, has as its object to provide a reliable resin-sealed semiconductor light receiving element with excellent durability with respect to environmental changes such as temperature cycles while using a transparent silicone resin, a manufacturing method thereof, and an electronic device using the same.

To solve the above problems, a resin-sealed semiconductor light receiving element of the present invention has a light receiving element mounted on a circuit board and sealed with a transparent resin. A mounting face of the circuit board on which the light receiving element is mounted is sealed with a transparent epoxy resin so that a light receiving surface of the light receiving element is exposed, and at least the light receiving surface of the light receiving element is sealed with a transparent silicone resin.

With this resin-sealed semiconductor light receiving element of the present invention, the mounting face of the circuit board on which the light receiving element is mounted is sealed with a transparent epoxy resin so that the light receiving surface of the light receiving element is exposed, and at least the light receiving surface of the light receiving element is sealed with a transparent silicone resin. Consequently, the mounting face of the circuit board and the connection points of the bonding wires on the circuit board are sealed by transparent epoxy resin, and given that the cure shrinkage rate of this transparent epoxy resin is low, there is little internal stress (internal deformation) on the cured resin. Therefore, defects such as the bonding wires breaking inside the resin or the resin peeling from the interface with the circuit board do not occur, and durability with respect to environmental changes such as temperature cycles is excellent, enabling high reliability to be obtained.

Also, at least the light receiving surface of the light receiving element is sealed with transparent silicone resin, and given that this transparent silicone resin has excellent light resistance to shortwave light, the light receiving characteristics of the light receiving element are not impaired.

A manufacturing method of a resin-sealed semiconductor light receiving element of the present invention includes the steps of mounting a plurality of light receiving elements on a circuit board, electrically connecting each of the light receiving elements to the circuit board, sealing a mounting face of the circuit board on which the light receiving elements are mounted with a transparent epoxy resin so that a light receiving surface of each of the light receiving elements is exposed, sealing the light receiving surfaces of the light receiving elements and a top surface of the transparent epoxy resin with a transparent silicone resin, and cutting the circuit board, the transparent epoxy resin and the transparent silicone resin by dicing to separate the light receiving elements on the circuit board.

The manufacturing method of a resin-sealed semiconductor light receiving element of the present invention enables a plurality of the resin-sealed semiconductor light receiving elements of the present invention to be manufactured at the same time.

Further, an electronic device of the present invention uses the resin-sealed semiconductor light receiving element of the present invention.

Since the electronic device of the present invention uses the resin-sealed semiconductor light receiving element of the present invention, similar effects to this resin-sealed semiconductor light receiving element can be achieved, and the durability of the electronic device itself is also improved.

### BRIEF DESCRIPTION OF THE DRAWINGS

FIG. 1 is a cross-sectional view showing an embodiment of a resin-sealed semiconductor light receiving element of the present invention.

FIG. 2 is a graph showing test results obtained by performing a temperature cycle test on the resin-sealed semiconductor light receiving element of the embodiment of FIG. 1 and a conventional semiconductor light receiving element.

FIG. 3 shows an embodiment of the manufacturing method of the present invention.

FIG. 4 shows an embodiment of the manufacturing method of the present invention.

FIG. 5 shows an embodiment of the manufacturing method of the present invention.

FIG. 6 shows an embodiment of the manufacturing method of the present invention.

FIG. 7 is a cross-sectional view showing a conventional resin-sealed semiconductor light receiving element.

### DESCRIPTION OF THE PREFERRED EMBODIMENTS

Hereinafter, embodiments of the present invention will be described in detail with reference to the drawings.

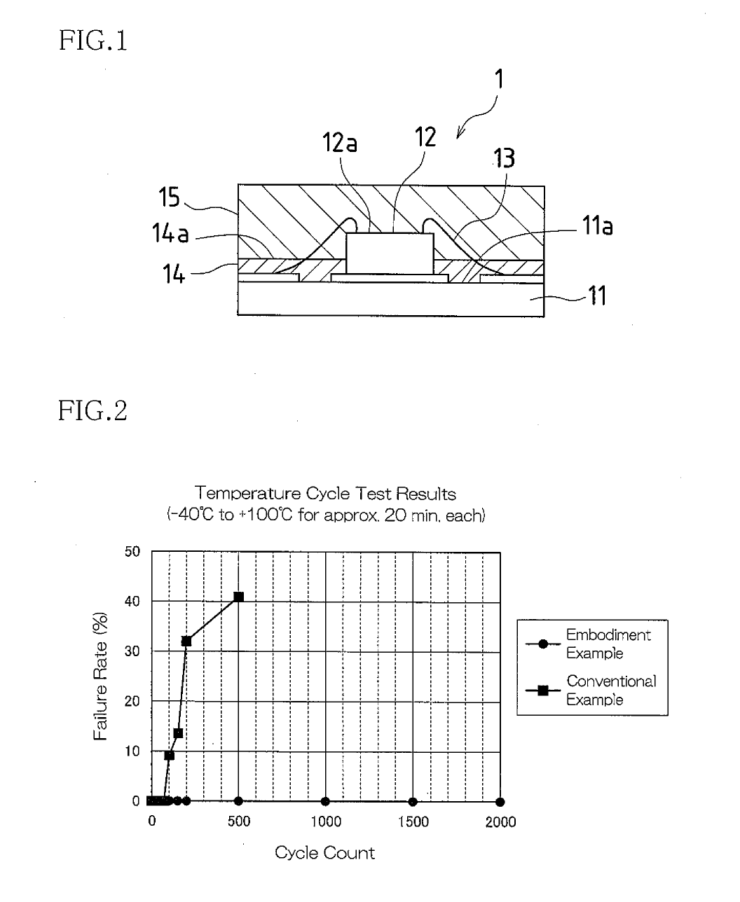

FIG. 1 is a cross-sectional view showing an embodiment of a resin-sealed semiconductor light receiving element of the present invention. The resin-sealed semiconductor light receiving element 1 of the present embodiment is used in a power monitor of a blue semiconductor laser in the field of optical pickups.

With the resin-sealed semiconductor light receiving element 1, a light receiving element chip 12 is fixed to a chip mounting portion 11d provided on a mounting face 11a of a circuit board 11 via a conductive paste or the like. Electrodes (not shown) of the light receiving element chip 12 are connected to wiring pattern terminals 11p provided on the mounting face 11a of the circuit board 11 by bonding wires 13 composed of Au.

The mounting face 11a of the circuit board 11 is sealed with a transparent epoxy resin layer 14 so that a light receiving surface 12a of the light receiving element chip 12 is exposed, and the light receiving surface 12a of the light receiving element chip 12 and a top surface 14a of the transparent epoxy resin layer 14 is sealed with a transparent silicone resin layer 15.

The transparent epoxy resin layer 14 and the transparent silicone resin layer 15 are formed by dripping (potting) a liquid transparent epoxy resin or transparent silicone resin into a mold provided so as to enclose the placement area of the light receiving element chip 12 and thermosetting the liquid resin using an oven or the like. The mold can be formed by insert molding on the circuit board 11 using a die or by adhesion on the circuit board 11 using an adhesive or the like.

This results in the mounting face 11a of the circuit board 11 and the connection points (second bonding points) of the bonding wires 13 on the circuit board 11 being sealed by the transparent epoxy resin layer 14, and the light receiving surface 12a of the light receiving element chip 12 being sealed by the transparent silicone resin layer 15.

Here, given that the cure shrinkage rate of transparent silicone resin is high in comparison to transparent epoxy resin, there is significant internal stress (internal deformation) on the cured transparent silicone resin. Therefore, when reliability tests such as the temperature cycle test, for example, are performed, defects such as the resin peeling from the interface with the circuit board or the bonding wires breaking inside the resin (primarily breakage at second bonding points) readily occur.

In contrast, there is little internal stress (internal deformation) on the cured transparent epoxy resin given that the cure shrinkage rate of transparent epoxy resin is small. Therefore, when the mounting face 11a of the circuit board 11 and the connection points of the bonding wires 13 on the circuit board 11 are sealed by the transparent epoxy resin layer 14 and the transparent epoxy resin layer 14 is cured, neither peeling of the transparent epoxy resin layer 14 from the interface with the mounting face 11a of the circuit board 11 nor breakage of the bonding wires 13 inside the transparent epoxy resin layer 14 readily occur. Sufficiently high reliability can be achieved without such peeling or breakage occurring when reliability tests such as the temperature cycle test are performed.

In the present embodiment, the thickness of the transparent epoxy resin layer 14 is controlled so that the mounting face 11a of the circuit board 11 and the connection points of the bonding wires 13 are securely sealed by the transparent epoxy resin layer 14, thereby enabling high reliability to be reproduced.

At the same time, the thickness of the transparent epoxy resin layer 14 is controlled so as to be less than the thickness of the light receiving element chip 12, so as to ensure that the light receiving surface 12a of the light receiving element chip 12 is not covered by the transparent epoxy resin layer 14. This enables the light receiving surface 12a of the light receiving element chip 12 to be covered and sealed by only the transparent silicone resin layer 15, resulting in light that has only passed through this transparent silicone resin layer 15 being incident on the light receiving surface 12a of the light receiving element chip 12.

Given that the resin-sealed semiconductor light receiving element 1 of the present embodiment is used in the power monitor of a blue semiconductor laser as aforementioned, a drop in the light receiving characteristics is forestalled by employing a configuration in which light that has only passed through this transparent silicone resin layer 15 having excellent light resistance to shortwave light is incident on the light receiving surface 12a of the light receiving element chip 12. If light were incident via the transparent epoxy resin layer 14, the transparent epoxy resin layer 14 would be degraded by the shortwave light, adversely affecting transmittance and reducing in the light receiving characteristics.

The graph in FIG. 2 shows test results obtained by performing the temperature cycle test on the resin-sealed semiconductor light receiving element 1 of the present embodiment and a conventional semiconductor light receiving element sealed using only transparent silicone resin. This test investigated the failure rate (bonding wire breakage rate) of the resin-sealed semiconductor light receiving element 1 and the conventional semiconductor light receiving element in an environment in which temperature cycles of −40° C. to +100° C. were repeated.

As evident from the FIG. 2 graph, extremely high reliability was obtained with the resin-sealed semiconductor light receiving element 1 of the present embodiment, with no failures occurring after 2000 cycles. In contrast, the conventional semiconductor light receiving element was markedly inferior in terms of reliability, with failures occurring at around 100 cycles and a 40% failure rate after 500 cycles.

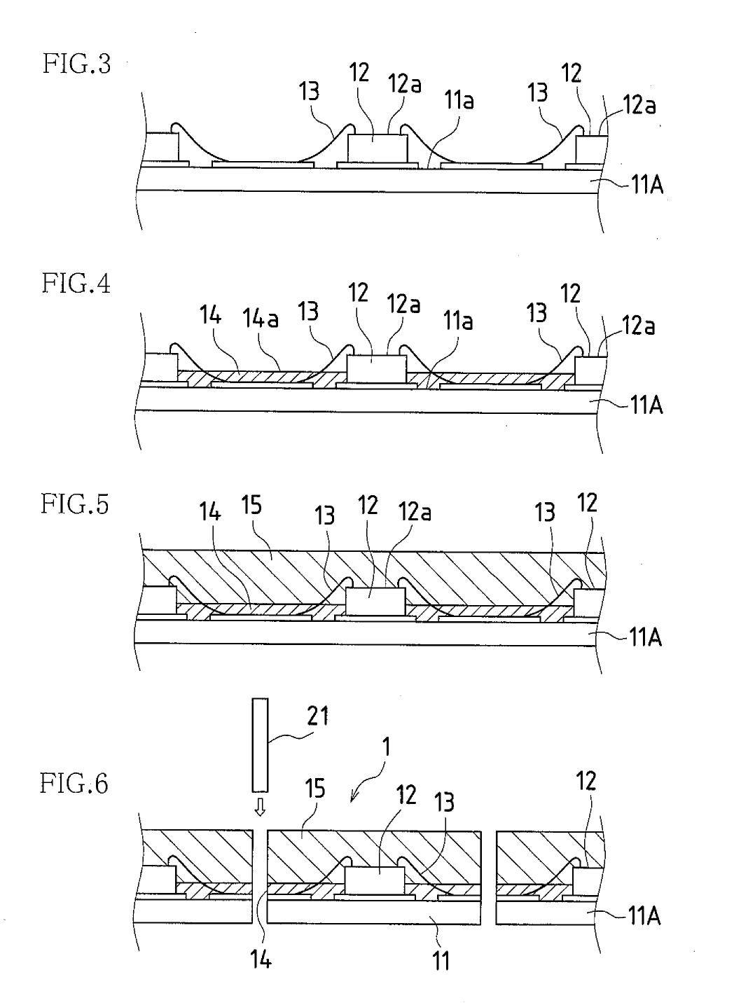

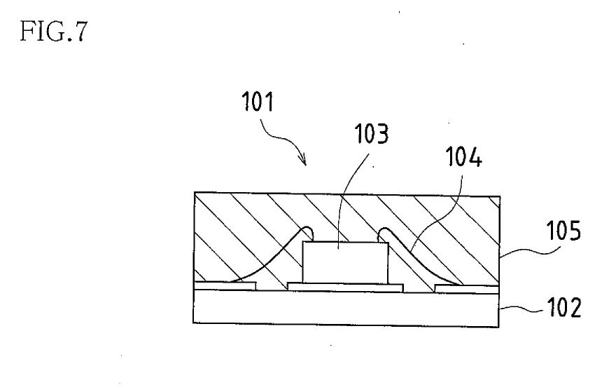

Next, an embodiment of the manufacturing method of the present invention will be described with reference to FIGS. 3 to 6. With the manufacturing method of the present embodiment, a plurality of the resin-sealed semiconductor light receiving elements 1 shown in FIG. 1 are manufactured at the same time.

Firstly, as shown in FIG. 3, a plurality of light receiving element chips 12 are arranged on and fixed to a mounting face 11a of a circuit board 11A by applying a conductive paste or the like to the mounting face 11a, and electrodes (not shown) of each light receiving element chip 12 are connected to wiring pattern terminals 11p of the circuit board 11A by bonding wires 13 composed of Au or the like.

Next, as shown in FIG. 4, the mounting face 11a of the circuit board 11A and the connection points (second bonding points) of the bonding wires 13 on the circuit board 11A are coated with a transparent epoxy resin layer 14 by dripping (potting) a liquid transparent epoxy resin onto the mounting face 11a of the circuit board 11A. The transparent epoxy resin layer 14 is then thermoset using an oven or the like to seal the mounting face 11a of the circuit board 11A and the connection points of the bonding wires 13 on the circuit board 11A with the transparent epoxy resin layer 14.

At this time, the transparent epoxy resin layer 14 is formed so as to be thinner than the light receiving element chips 12, exposing the light receiving surfaces 12a of the light receiving element chips 12.

Next, as shown in FIG. 5, the top surface 14a of the transparent epoxy resin layer 14 and the light receiving surfaces 12a of light receiving element chips 12 are coated with a transparent silicone resin layer 15 by dripping (potting) a liquid transparent silicone resin. The transparent silicone resin layer 15 is then thermoset using an oven or the like to seal the transparent epoxy resin layer 14 and the light receiving surfaces 12a of light receiving element chips 12 with the transparent silicone resin layer 15.

Next, as shown in FIG. 6, the circuit board 11A, the transparent epoxy resin layer 14 and the transparent silicone resin layer 15 are divided by cutting along prescribed lines by dicing using a blade 21 to separate the light receiving element chips 12 and obtain a plurality of resin-sealed semiconductor light receiving elements 1 composed of the circuit board 11, the light receiving element chip 12, the bonding wires 13, the transparent epoxy resin layer 14, the transparent silicone resin layer 15 and the like as shown in FIG. 1.

Here, the dicing sheet is stuck to the underside of the circuit board 11A and dicing is performed from the sealing resin side, but the dicing sheet may conversely be stuck to the top surface of the sealing resin and dicing performed from the circuit board 11A side.

The present invention encompasses not only a resin-sealed semiconductor light receiving element but an electronic device that applies this resin-sealed semiconductor light receiving element. The electronic device is an optical pickup or the like.

The present invention may be embodied in other forms without departing from the gist or essential characteristics thereof. The foregoing embodiments are therefore to be considered in all respects as illustrative and not limiting. The scope of the invention is indicated by the appended claims rather than by the foregoing description, and all modifications and changes that come within the meaning and range of equivalency of the claims are intended to be embraced therein.

What is claimed is:

1. A resin-sealed semiconductor light receiving element in which a light receiving element mounted on a circuit board is sealed with a transparent resin,
wherein a mounting face of the circuit board on which the light receiving element is mounted is sealed with a transparent epoxy resin so that a light receiving surface of the light receiving element is exposed, and at least the light receiving surface of the light receiving element is sealed with a transparent silicone resin.

2. A manufacturing method of a resin-sealed semiconductor light receiving element, comprising the steps of:
mounting a plurality of light receiving elements on a circuit board;
electrically connecting each of the light receiving elements to the circuit board;
sealing a mounting face of the circuit board on which the light receiving elements are mounted with a transparent epoxy resin so that a light receiving surface of each of the light receiving elements is exposed;
sealing the light receiving surfaces of the light receiving elements and a top surface of the transparent epoxy resin with a transparent silicone resin; and
cutting the circuit board, the transparent epoxy resin and the transparent silicone resin by dicing to separate the light receiving elements on the circuit board.

3. An electronic device using a resin-sealed semiconductor light receiving element as claimed in claim 1.
